(19) United States
(12) Patent Application Publication
(10) Pub. No.: US 2014/0308515 A1
(43) Pub. Date: Oct. 16, 2014

(54) ADHESIVE TAPE

(71) Applicant: HON HAI PRECISION INDUSTRY CO., LTD., New Taipei (TW)

(72) Inventors: MING-JEN CHANG, New Taipei (TW); CHANG-CHIN WU, New Taipei (TW)

(21) Appl. No.: 13/942,702

(22) Filed: Jul. 16, 2013

(30) Foreign Application Priority Data
Apr. 10, 2013 (TW) 102112762

(51) Int. Cl. H01L 21/683

(52) U.S. Cl. CPC H01L 21/6836
USPC 428/354

(57) ABSTRACT

An adhesive tape is disclosed. The adhesive tape includes a base layer made of light guide materials, a first adhesive layer, and a second adhesive layer. The base layer is positioned and bonded between the first adhesive layer and the second adhesive layer. In use, a first workpiece is adhered to the first adhesive layer, and a second workpiece is adhered to the second adhesive layer. When the first workpiece is required to delaminate, depart or removed from the second workpiece, even if the first workpiece and the second workpiece are made of non-transparent or opaque materials, light can enter the base layer from and through the incident surface, and then emits out from the two emitting surfaces. Thus, the first workpiece can be easily removed from the second workpiece due to the UV deactivation of adhesiveness of the adhesive layer through the incident surface of the base layer.

### BACKGROUND

1. Technical Field

The present disclosure relates to adhesive tapes, and particularly to a UV deactivating adhesive tape and a double-sided UV deactivating adhesive tape for bonding one or more workpieces.

2. Description of the Related Art

A light deactivating adhesive tape is a type of adhesive tape whose adhesiveness is reduced dramatically when irradiated by light, such as UV light or infrared light. The light deactivating adhesive tape, such as a UV deactivating adhesive tape, is used for bonding transparent members. When the UV deactivating adhesive tape is required to be peeled off from the bonded transparent members, a UV light is employed to irradiate the bonded members, such that the adhesiveness of the adhesive tape is reduced, and thereby the adhesive tape is easily peeled off from the previously-bonded members. However, if the bonded members are not transparent, the light deactivating adhesive tape is not applicable or does not work.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views.

FIG. 1 is a cross-sectional view of a first embodiment of an adhesive tape.

FIG. 2 is a cross-sectional view of the adhesive tape of FIG. 1 in a usage state.

FIG. 3 is a cross-sectional view of a second embodiment of an adhesive tape.

FIG. 4 is a cross-sectional view of a third embodiment of an adhesive tape.

### DETAILED DESCRIPTION

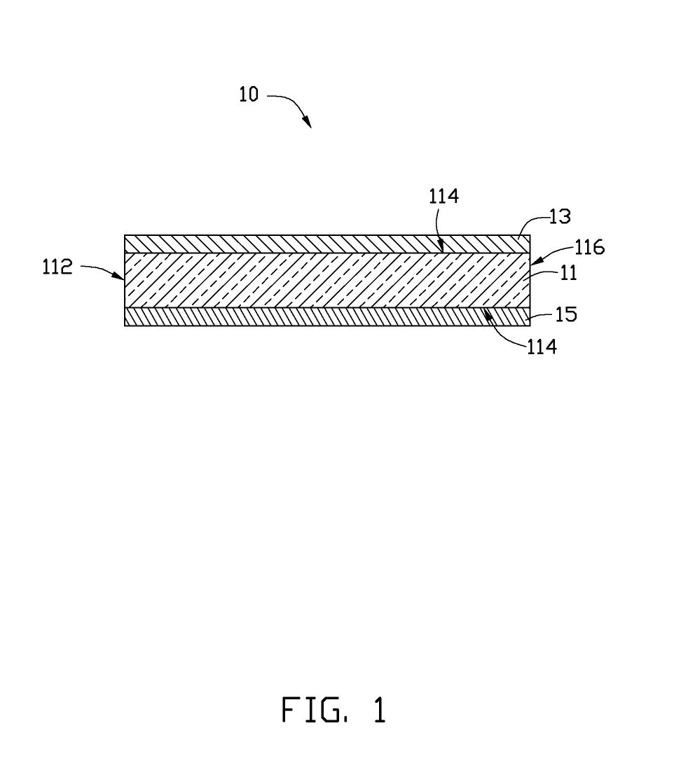

FIG. 1 shows a first embodiment of an adhesive tape 10. The adhesive tape 10 includes a base layer 11 made of light guide materials, a first adhesive layer 13, and a second adhesive layer 15. The base layer 11 is positioned and formed between the first adhesive layer 13 and the second adhesive layer 15. The base layer 11 includes an incident surface 112, two emitting surfaces 114 opposite to each other, and an end surface 116 opposite to the incident surface 112. The two emitting surfaces 114 are positioned on opposite sides of the incident surface 112, and are parallel to each other. The incident surface 112 interconnects the two emitting surfaces 114. Light enters the base layer 11 through the incident surface 112, and then emits out from the two emitting surfaces 114 of the base layer 11. The first adhesive layer 13 and the second adhesive layer 15 are placed and bonded on the two emitting surfaces 114 (due to having good or sufficient adhesiveness), respectively. The first adhesive layer 13 and the second adhesive layer 15 are made of UV deactivating adhesive material. (The principle of operation of the UV deactivating adhesive is directly in contrast to the UV activating adhesive, that is to say, the exposure to UV radiation causes the UV deactivating adhesive material to diminish adhesiveness or adhesion property, whereas the same UV radiation would cause the UV activating adhesive to gain adhesion instead.) The base layer 11 can be a light guide plate or a light guide film. A material of the light guide plate or the light guide film can be selected from the group consisting of polymethyl methacrylate (PMMA), polycarbonate (PC), and any other suitable transparent resin material. In other embodiments, the first adhesive layer 13 and the second adhesive layer 15 can be made of other light deactivating adhesives, such as infrared deactivating adhesives. The end surface 116 can be coated by a reflective layer, such that light entering from the incident surface 112 can only emit out from the emitting surfaces 114, for improving a light utilization efficiency.

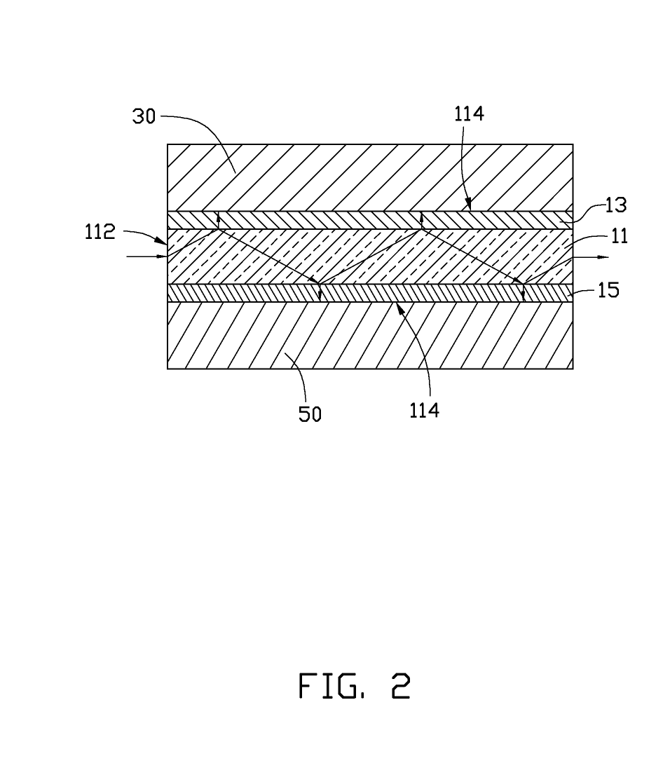

FIG. 2 shows that the first embodiment in use, a first workpiece 30 is adhered to the first adhesive layer 13, and a second workpiece 50 is adhered to the second adhesive layer 15, respectively, such that the first workpiece 30 indirectly bonds with the second workpiece 50. Even if the first workpiece 30 and the second workpiece 50 are made of non-transparent or opaque materials, light can still enter the base layer 11 through the incident surface 112, and then emits out from the two emitting surfaces 114 thereof. Thus, the light irradiates the first adhesive layer 13 and the second adhesive layer 15, respectively, so that adhesiveness or adhesion of the first adhesive layer 13 and the second adhesive layer 15 is thereby reduced, and the first workpiece 30 is easily removed from the second workpiece 50.

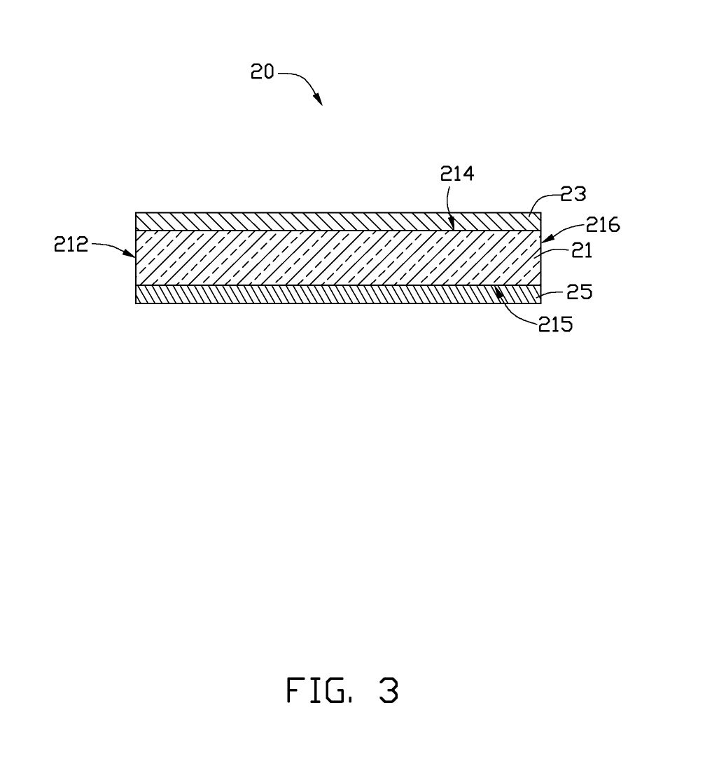

FIG. 3 shows a second embodiment of an adhesive tape 20. The adhesive tape 20 includes a base layer 21 made of light guide materials, an adhesive layer 23, and a coating layer 25. The base layer 21 includes an incident surface 212, an emitting surface 214, a side surface 215, and an end surface 216 opposite to the incident surface 212. The emitting surface 214 and the side surface 215 are positioned on opposite sides of the incident surface 212, and are parallel to each other. The incident surface 212 interconnects the emitting surface 214 with the side surface 215. Light enters the base layer 21 through the incident surface 212, and then emits out from the emitting surface 214. The adhesive layer 23 is placed and bonded on the emitting surface 214 of the base layer 21 (due to having good or sufficient adhesiveness for bonding). The coating layer 25 is placed and coated on the side surface 215 of the base layer 21. The adhesive layer 23 is made of a UV deactivating adhesive material. The coating layer 25 is made of an adhesive agent to form another adhesive layer, or to be made of a coating material for shielding light or protection.

In use, the first workpiece 30 is adhered to the adhesive layer 23. Even if the first workpiece 30 is made of non-transparent or opaque materials, light can enter the base layer 21 through the incident surface 212, and then emits out from the emitting surface 214 of the base layer 21. Thus, the light irradiates the adhesive layer 23, so that adhesiveness of the adhesive layer 23 is reduced dramatically or significantly, so that the adhesive layer 23 is easily peeled off from the first workpiece 30.

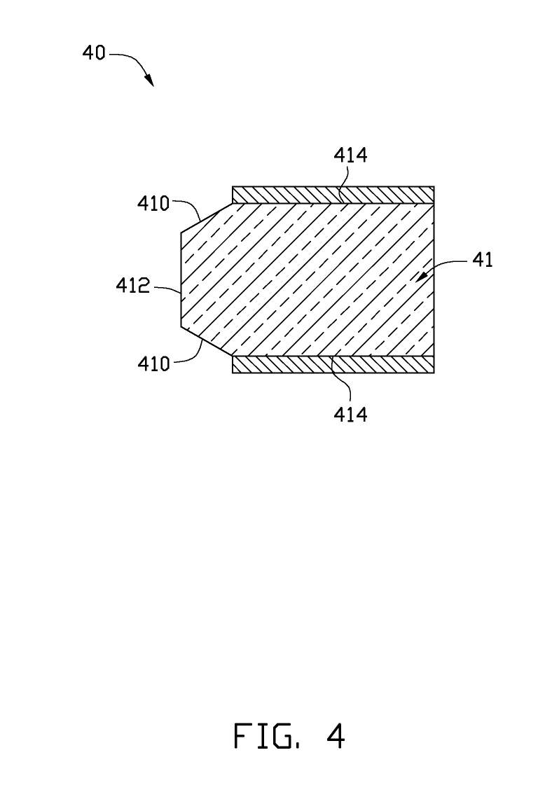

FIG. 4 shows a third embodiment of an adhesive tape 40. The adhesive tape 40 has a similar structure to that of the first embodiment of the adhesive tape 10. However, the base layer 41 further includes two connection surfaces 410 in addition to an incident surface 412. One connection surface 410 interconnects one end of the incident surface 412 with one emitting surface 414, and the other connection surface 410 interconnects an opposite end of the incident surface 412 with the other emitting surface 414.

In other embodiments, the emitting surfaces 114, 214, 414 and the incident surfaces 112, 212, 412 can be arranged in other arrangements or configurations as required for use, as long as light can enter the base layer 11, 21, 41 through the incident surfaces 112, 212, 412, and then emit out from the emitting surfaces 114, 214, 414 of the base layer 11, 21, 41.

It is to be understood, however, that even through numerous characteristics and advantages of the disclosure have been set forth in the foregoing description, together with details of the structure and function of the embodiments, the disclosure is illustrative only, and changes may be made in detail, especially in the matters of shape, size, and arrangement of parts within the principles of the embodiments to the full extent indicated by the broad general meaning of the terms in which the appended claims are expressed.

What is claimed is:

1. An adhesive tape, comprising:
a first adhesive layer made of a light deactivating adhesive;
a second adhesive layer made of a light deactivating adhesive; and
a base layer made of a light guide material and placed and bonded between the first adhesive layer and the second adhesive layer, the base layer comprising an incident surface and two emitting surfaces, wherein the first adhesive layer and the second adhesive layer are placed and bonded on the two emitting surfaces, respectively, and a light is capable of entering the base layer through the incident surface and then emitting out from the two emitting surfaces of the base layer, whereby the adhesiveness of the first adhesive layer and of the second adhesive layer are diminished.

2. The adhesive tape of claim 1, wherein the first adhesive layer is made of a UV deactivating adhesive or an infrared deactivating adhesive.

3. The adhesive tape of claim 1, wherein the second adhesive layer is made of UV deactivating adhesive or an infrared deactivating adhesive.

4. The adhesive tape of claim 1, wherein the incident surface of the base layer interconnects the two emitting surfaces thereof, and the two emitting surfaces are parallel to each other.

5. The adhesive tape of claim 1, wherein the base layer is a light guide plate or a light guide film.

6. The adhesive tape of claim 1, wherein the base layer further comprises two connection surfaces, each of the two connection surfaces interconnects one end of the incident surface with one of the two emitting surfaces.

7. The adhesive tape of claim 1, wherein the base layer further comprises an end surface opposite to the incident surface, the end surface is coated by a reflective layer.

8. The adhesive tape of claim 1, wherein when the light enters the base layer through the incident surface and then emits out from the two emitting surfaces of the base layer, whereby the adhesiveness of the first adhesive layer and of the second adhesive layer are significantly diminished.

9. An adhesive tape, comprising:
an adhesive layer made of a UV deactivating adhesive;
a coating layer; and
a base layer made of a light guide material and placed and bonded between the adhesive layer and the coating layer, the base layer comprising an incident surface, an emitting surface, and a side surface, wherein the adhesive layer is placed and bonded on the emitting surface, the coating layer is placed and bonded on the side surface, light is capable of entering the base layer through the incident surface and then emitting out from the emitting surface of the base layer, whereby the adhesiveness of the adhesive layer is significantly diminished.

10. The adhesive tape of claim 9, wherein the emitting surface of the base layer is parallel to the side surface thereof.

11. The adhesive tape of claim 9, wherein the base layer is a light guide plate or a light guide film.

12. The adhesive tape of claim 9, wherein the coating layer comprises an another adhesive layer.

13. The adhesive tape of claim 9, wherein the coating layer is constructed for shielding light or protection.

14. The adhesive tape of claim 9, wherein the base layer further comprises an end surface opposite to the incident surface, the end surface is coated by a reflective layer.
